(19) United States
(12) Patent Application Publication
(10) Pub. No.: US 2005/0234220 A1
(43) Pub. Date: Oct. 20, 2005

(54) Low density, low dielectric, metalizable polymer films

(76) Inventors: Tadanori Koga, Stony Brook, NY (US); Miriam Rafailovich, Plainview, NY (US); Benjamin Chu, Setauket, NY (US); John L. Jerome, Stony Brook, NY (US)

Correspondence Address: HOFFMANN & BARON, LLP, 6900 JERICHO TURNPIKE, SYOSSET, NY, 11791, US

(21) Appl. No.: 10/933,121

(22) Filed: Sep. 2, 2004

Related U.S. Application Data
(60) Provisional application No. 60/499,421, filed on Sep. 2, 2003.

(51) Int. Cl. C23C 16/00

(52) U.S. Cl. 528/481

(57) ABSTRACT

A method for forming a polymer film with improved physical properties and films formed by the method. The method includes contacting a polymer film with a supercritical fluid, preferably supercritical carbon dioxide or supercritical ethane, at high pressure and high temperature conditions which correspond to the density fluctuation ridge conditions of the supercritical fluid. The films formed by this method have a lower density, a reduced glass transition temperature, an increased nanoscale-porosity, a decreased dielectric constant and increased adhesion to a metallic layer.

### BACKGROUND OF INVENTION

This application claims priority based on provisional application Ser. No. 60/499,421, filed on Sep. 2, 2003, which is incorporated herein by reference in its entirety.

The present invention is a method for reducing the density of polymer films. In particular, the present invention relates to reducing the density of polymer films by exposing them to supercritical fluids (“SCFs”).

In recent years, the chemical manufacturing industry has been turning to “green solvent” technologies to replace organic solvents that have raised serious environmental concerns. Unlike organic solvents which require special handling and involve significant disposal costs, “green solvents” such as supercritical fluids are relatively inexpensive and environmentally friendly. Generally, physical properties of SCFs such as density and viscosity, lie between those of liquid and gas states. Because of these unique features, there has been enormous interest in the use of SCFs as solvents for chemical reactions. The physicochemical characteristics change greatly with variations in temperature and pressure, and the control of these properties may lead to a significant improvement in reaction rate and/or selectivity. Supercritical fluids have been used for the recovery of organics from shale oil, crude oil de-asphalting and dewaxing, coal processing, selective extraction of fragrances, oils and impurities from agricultural and food products, pollution control, combustion and a variety of other applications.

Organic solvents are widely used in the polymer industry and they have been targeted for replacement by a more environment friendly substitute. However, no “green solvent” substitutes have been found for many applications. Therefore, there is an increasing need to find “green solvent” substitutes for organic solvents that are presently being used in processing different polymers.

### SUMMARY OF THE INVENTION

The present invention relates to polymer films with improved physical properties and methods for forming such films. The polymer films are formed by a method which includes contacting a polymer film with a supercritical fluid (“SCF”), preferably supercritical carbon dioxide (“scCO₂”) or supercritical ethane (“scC₂H₆”). The SCF contacts the polymer film at high pressure and high temperature conditions, which correspond to the SCF's density fluctuation ridge conditions. The films formed by this method have a density that is decreased by at least 20% and preferably 30%, a reduced glass transition temperature, an increased nanoscale-porosity, a changed index of refraction and a decreased dielectric constant. The polymer films preferably include a polystyrene or a poly(methyl methacrylate) and can also include nanoscale inorganic particles, preferably nanoscale inorganic particles that include one or more noble metals. These nanoscale particles have diameters ranging in size from about 1 nm to about 100 mm, preferably from about 1 nm to about 50 nm, and most preferably from about 2 nm to about 20 nm.

The present invention also includes a method for coating a polymer film. This method includes forming a polymer film; contacting said polymer film with a supercritical fluid (“SCF”); flash evaporating the SCF; and contacting the polymer film with a metallic vapor. The polymer film preferably includes a polystyrene or a poly(methyl methacrylate) and can also include nanoscale inorganic particles, preferably nanoscale inorganic particles which include noble metals. The metallic vapor can include aluminum, tin, silver, gold or other metals known to those skilled in the art.

The SCF is preferably either supercritical carbon dioxide (“scCO₂”) or supercritical ethane (“scC₂H₆”). The SCF contacts the polymer film at high pressure and high temperature conditions for at least 30 minutes, preferably from 30 minutes to five hours and most preferably from one to three hours. After more than three hours of contact, the changes in the properties of the film are insignificant. The high temperature and the high pressure conditions correspond to the SCF's density fluctuation ridge conditions.

### BRIEF DESCRIPTION OF THE FIGURES

Other objects and many attendant features of this invention will be readily appreciated as the invention becomes better understood by reference to the following detailed description when considered in connection with the accompanying drawings wherein:

FIG. 1(a) is a graph which shows the x-ray reflectivity (“XR”) profile for a frozen polystyrene thin film plotted as a function of the momentum transfer normal to the surface, q_{z}.

FIG. 1(b) is a graph which shows the dispersion profile used for the refinement of the measured reflectivity of the frozen polystyrene thin film in FIG. 1(a).

FIG. 2(a) is a graph which shows the density for two frozen polystyrene thin films as a function of the scaled film thickness (“L₀/R_{g}”).

FIG. 2(b) is a graph which shows the linear dilation (“S_{f}”) for two frozen polystyrene thin films as a function of the scaled film thickness (“L₀/R_{g}”).

FIG. 3 shows an atomic force microscopy (“AFM”) scan of the surface topography for a frozen polystyrene film.

FIG. 4 is a graph which shows the temperature dependence of the amplitude response of shear force (“Δx”) for a frozen polystyrene film.

FIG. 5 is a graph which shows the refractive indices (“n_{f}”) of frozen polystyrene films with the different linear dilation (“S_{f}”) values.

FIG. 6(a) is a graph which shows the x-ray reflectivity (“XR”) profiles for frozen (circles) and unexposed (squares) polystyrene/chromium films plotted as a function of the moment transfer normal to the surface, q_{z}. The solid lines correspond to the best-fits to the data using the dispersion profiles shown in FIG. 6(b).

FIG. 6(b) is a graph which shows the dispersion profiles used for the refinement of the measured reflectivities of the frozen (solid line) and unexposed (dotted line) polystyrene/chromium films in FIG. 6(a). It should be noted that the thicknesses of the chromium layers for both specimens were slightly different since the chromium layer were separately deposited.

FIG. 7(a) is a graph which shows the x-ray reflectivity (“XR”) profiles for frozen (circles) and unexposed (squares) poly(methyl methacrylate)/chromium films plotted as a function of the moment transfer normal to the surface, q_{z}. The solid lines correspond to the best-fits to the data using the dispersion profiles shown in FIG. 7(b).

FIG. 7(b) is a graph which shows the dispersion profiles used for the refinement of the measured reflectivities of the frozen (solid line) and unexposed (dotted line) poly(methyl methacrylate)/chromium films in FIG. 7(a).

FIG. 8 is a graph which shows the linear dilation (“S_{f}”) for deuterated-polystyrene thin film in scCO₂ and scC₂H₆ as a function of pressure.

FIG. 9(a) is a graph which shows the x-ray reflectivity (“XR”) profiles for frozen (circles) and unexposed (squares) polystyrene/gold films plotted as a function of the moment transfer normal to the surface, q_{z}. The solid lines correspond to the best-fits to the data using the dispersion profiles shown in FIG. 9(b).

FIG. 9(b) is a graph which shows the dispersion profiles used for the refinement of the measured reflectivities of the frozen and unexposed polystyrene/gold films in FIG. 9(a).

FIG. 10 shows an atomic force microscopy (“AFM”) scan of the surface topography for a frozen polystyrene/gold film 1 R_{g} thick.

FIG. 11(a) is a graph which shows the x-ray reflectivity (“XR”) profiles for frozen and unexposed polystyrene/clay films plotted as a function of the moment transfer normal to the surface, q_{z}. The solid lines correspond to the best-fits to the data using the dispersion profiles shown in FIG. 11(b).

FIG. 11(b) is a graph which shows the dispersion profiles used for the refinement of the measured reflectivities of the frozen and unexposed polystyrene/clay films in FIG. 111(a).

FIG. 12 is a graph which shows the temperature dependence of the amplitude response of shear force (“Δx”) for a polystyrene/gold film 2 R_{g} thick: before (squares) and after (circles) exposure to scCO₂.

FIG. 13 is a graph which shows the schematic diagram of high pressure cell; (A) thermocouple, (B) heater, (C) backup ring, (D) Teflon o-ring, (E) retainer, (F) sapphire windows, (G) chamber, (H) Teflon gasket (I) nylon gasket, (J) Si wafer (K) Al spacer, (L) cover, (M) main nut, (N)HF4 connection.

FIG. 14 is a graph which shows the schematic diagram of experimental configuration for CO₂ experiments: (CL) CO₂ cylinder, (SP) hand operated syringe pump, (PG) pressure gauge, (V1) inlet valve, (V2) release valve, (T) pressure transducer, (TC) temperature controller, (CE) high-pressure chamber.

FIG. 15 is a graph which shows the schematic phase diagram of CO₂ near the critical point. Critical point is denoted as CP.

### DETAILED DESCRIPTION OF THE INVENTION

The critical point (“CP”) marks the end of the vapor-liquid coexistence curve. A fluid is referred to as supercritical when the temperature and pressure are higher than the corresponding critical values. Above the critical temperature, there is no phase transition in that the fluid cannot undergo a transition to a liquid phase, no matter how much the pressure is increased. There are significant changes in several important properties of a pure liquid as its temperature and pressure are increased and approach the thermodynamic critical point. Under thermodynamic equilibrium conditions, the visual distinction between liquid and gas phases and the difference between the liquid and gas densities disappear at and above the critical point. Moreover, at and above the critical point, significant changes occur in viscosity, conductivity, surface tension and constant-pressure heat capacity.

In the present invention, a polymeric film is contacted with a supercritical fluid (“SCF”), preferably supercritical CO₂ (scCO₂), to reduce the density of the film. Supercritical CO₂ (scCO₂), which has a readily accessible critical temperature (T_{c}) of 31.3° C. and a critical pressure (P_{c}) of 7.38 MPa, is an attractive candidate to replace organic solvents in various polymer processes. However, since the number of polymers that are miscible in scCO₂ is very small, it has not been widely used in polymer processing applications. It has recently been shown using in situ neutron reflectivity that a wide variety of polymer thin films can swell as much as 30-60% when exposed to scCO₂ within a narrow temperature and pressure regime, known as the “density fluctuation ridge.” The density fluctuation ridge defines the maximum density fluctuation amplitude for CO₂. The anomalous dilation increases as the temperature and pressure approaches the critical point of CO₂ (Tc=31.3° C. and Pc=7.38 MPa). Furthermore, it has been found that the in situ film quality, i.e., density, roughness and film thickness, can be frozen by flash evaporation of CO₂. By using these special characteristics of scCO₂ (and other SCFs), the method of the present invention forms low-density polymer films.

The present invention is a method for reducing the density of polymer films using SCFs and the films produced using this method. In preferred embodiments, the density of polymer films can be reduced by more than 20%, and preferably by more than 30%. This density reduction is accomplished by exposure to supercritical fluids, preferably supercritical carbon dioxide (“scCO₂”), within a narrow temperature and pressure regime known as the “density fluctuation ridge,” or where the measured density fluctuations in CO₂ are maximal.

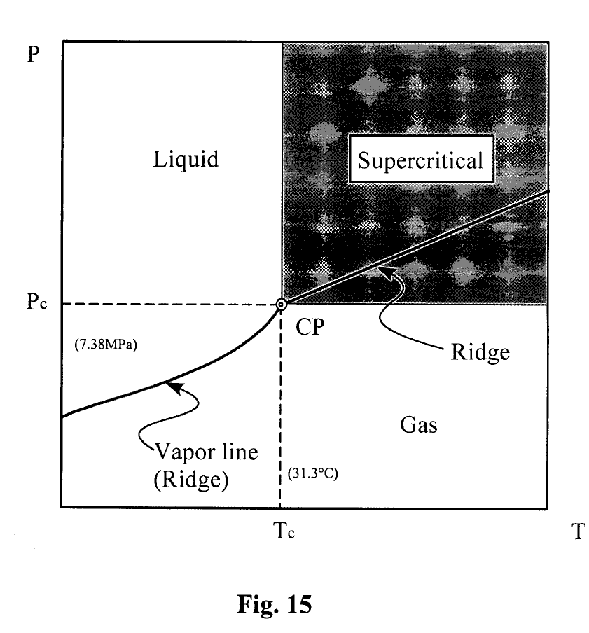

In one embodiment of the present invention, spin cast polymer thin films are placed in a high pressure chamber and immersed in scCO₂ at two different conditions, (i) T=36° C. and P=8.2 M Pa and (ii) T=50° C. and P=10 M Pa, for 2 hours. These temperature and pressure conditions are chosen since they correspond to the density fluctuation ridge in the vicinity of critical point of CO₂ and can still be tuned within the experimental resolution. The films are then quickly depressurized to atmospheric pressure within 10 seconds in order to vitrify the swelling structures. FIG. 15 shows how the density fluctuation ridge forms along the extension of the coexistence curve of gas and liquid in the pressure-temperature phase diagram in the critical temperature/critical pressure quadrant.

When polymers are immersed in SCFs such as scCO₂, a uniform swelling occurs where the degree of swelling can be varied by the film molecular weight and elasticity. Different microcopies and x-ray scattering are used to measure the reduced density and confirm that the swelling does not produce large voids. The reduced density was then observed to result in a reduction of the dielectric constant, k.

Using neutron reflectivity (NR), it has been found that CO₂ can be sorbed to a large extent in polymer thin films even when the bulk miscibility of the polymers with CO₂ is very poor. Films made of polymers, such as polystyrene (PS) and poly(methyl methacrylate) (PMMA), were observed to swell by approximately 30% as a function of temperature and pressure near T≈T_{c}. These temperature and pressure conditions are well below the glass transition temperatures (T_{g}˜100° C.) for the polymers. The swelling was reversible and reached a maximum at pressures and temperatures along the density fluctuation ridge that defines the maximum density fluctuation amplitude for CO₂. The functional form of the dilation amplitude followed that of the density fluctuations as a function of temperature and pressure. In addition, the NR measurements showed that uniform density films were formed with a maximum roughness of less than 25 Å. This indicated that the swelling was not associated with phase separation (as previously reported for the bulk films), which ultimately leads to a large void formation when CO₂ is rapidly evaporated. Rather, it was determined that in order to suppress the large density fluctuations, CO₂ became solubilized in the viscous polymer films.

By controlling the pressure and temperature variations, the magnitude of the density fluctuations on the effective glass transition, interfacial roughness and chain diffusion in the swollen films can be controlled. Once these changes have been achieved, they can be frozen by flash evaporation of CO₂, yielding stable low density and low index of refraction films.

This low-density polymer thin film can be used for creating well adhered metal/polymer interfaces. The polymers used to make the films of the present invention are normally hydrophobic and have poor adhesion to metallic coatings. Exposure to scCO₂ significantly introduces free volume, i.e., nanometer-scale porosity, which allows easy penetration of metallic vapors and subsequent deposition of a well adhered metallic layer.

It has been determined that the anomalous swelling depends upon only the magnitude of the density fluctuations in supercritical fluids. That is, there is no substance dependence. Therefore, this method is applicable for all supercritical fluids (SCFs), e.g., water, propane, methane, ethane, and Xenon. Moreover, this method allows the maximum/minimum degree of the dilation/density of polymer films to be controlled by optimizing a combination of SCFs and polymers.

The present invention can be further applicable to polymeric nanocomposite thin films. Nanoscale noble inorganic particles have been added to polymers for years to significantly enhance various physical properties such as UV absorption, electrical conductivity, optical dispersion. The increase in nano-scale porosity introduced by scCO₂ exposure enables low density polymeric nanocomposite thin films to be created. The major advantage is that the porosity can be created without further processing of the polymer with corrosive solvents or heat treatments which may oxidize or alter the surface properties of the particles.

### EXAMPLES

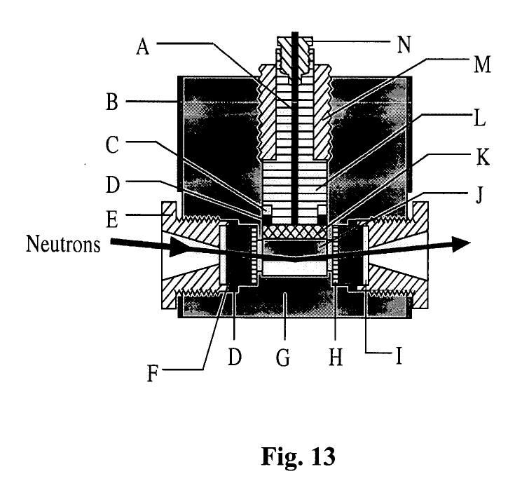

A high pressure cell was used for the experiments. The body of the high pressure cell was machined from 4340 steel. Sapphire was selected for the optical window material because of its high transparency for neutrons (more than 90%). Furthermore, sapphire has high tensile strength (elastic limit 448 MPa), resistance to corrosion, high-energy damage threshold, and low absorbance. Two cylindrical sapphire windows (2.4 cm thick, o.d. 5 cm) were installed for transmitting the incident beam and for receiving the reflected beams. The sealing was achieved by a combination of a Teflon and a nylon gasket placed between the sapphire windows. A diagram of the cell is shown in FIG. 13.

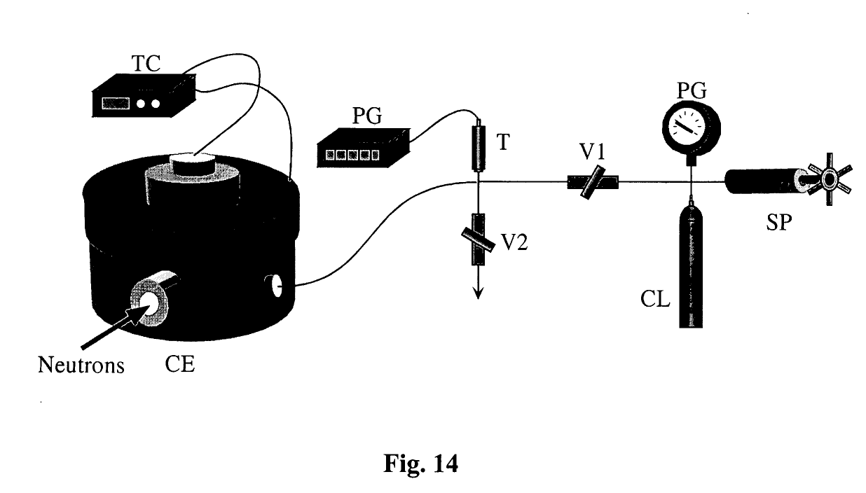

The cell had a volume of about 10 ml and a maximum pressure rating of 140.0 MPa. CO₂ used in the experiments had a purity of 99.9% and was loaded into the cell by means of a hand operated syringe pump (HIP Equip.) to the desired pressure. Prior to pressurization, the air space was purged with the gas at low pressure. FIG. 14 shows the general arrangement of the equipment used for the experiments. CO₂ pressure inside the cell was monitored using an OMEGADYNE pressure transducer (TH-1) with a pressure gauge meter (INFS-0001-DC1). The temperature of the cell was controlled by a temperature controller (CAL Controls) equipped with heaters that were installed on the outer side of the cell and a thermocouple (Rama Co.). The temperature of the system was controlled with an accuracy of ±0.1° C. and the stability of pressure during the measurements was less than ±0.2%.

The polymer thin films were spun cast on hydrofluoric acid (“HF”) etched, cleaned Si substrates and were pre-annealed for 5 hours in a vacuum of 10⁻⁶ Torr at 150° C. in order to remove residual solvent and spin induced stress. The films were then placed in the high pressure chamber and immersed in scCO₂ at the ridge conditions for an annealing time of 2 hours, and then quickly depressurized to atmospheric pressure within 10 seconds to vitrify the swelling structures.

The maximum temperature and pressure for the high pressure chamber were 70° C. and 100 MPa, respectively. Since the anomalous swelling occurs along the density fluctuation ridge shown in FIG. 15 and increases as the temperature approaches the critical point (Tc=31.3° C. and Pc=7.38 MPa), the degree of dilation of polymer films, i.e., the degree of the density, as a function of temperature and pressure can be controlled along the ridge. Operating CO₂ conditions used for the test were (i) T=36° C. and P=8.2 MPa and (ii) T=50° C. and P=10.0 MPa. These temperature and pressure conditions were chosen since they correspond to the density fluctuation ridge in the vicinity of the critical point of CO₂ and can still be tuned within the experimental resolution.

The examples set forth below serve to provide further appreciation of the invention but are not meant in any way to restrict the scope of the invention.

### EXAMPLE 1

Two types of hydrogenated polystyrene (“PS”) were used in this example. One hydrogenated polystyrene (PS1) had a molecular weight (M_{w}) of 2.0×10⁵, while the second hydrogenated polystyrene (PS2) had a molecular weight (M_{w}) of 6.5×10⁵. Both polymers were obtained from Polymer Lab and both had polydispersity indices of 1.05. The hydrogenated polystyrenes were spun cast on HF etched silicon (“Si”) substrates to form thin films which were pre-annealed for 5 hours in a vacuum of 10⁻⁶ Torr at 150° C. The films were first placed in the high pressure chamber and immersed in scCO₂ at the ridge condition (T=36° C. and P=8.2 MPa) for an annealing time of 2 hours, and then quickly depressurized to atmospheric pressure within 10 seconds to vitrify the swelling structures. The film was then subjected to various testing procedures that include x-ray reflectivity, atomic force microscopy (“AFM”) and spectroscopic ellipsometry.

The ridge of CO₂ is determined from the calculation of the isothermal compressibility, ↓_{T}, based on P-V-T curve. If the κ_{T} values are known as a function of temperature and pressure, the thermodynamic behavior can be characterized in terms of density fluctuation of SCFs. In order to obtain the κ_{T} values of CO₂, the equation of state of CO₂ given by Huang et al is used. As shown in FIG. 15, the ridge forms along the extension of the coexistence curve of gas and liquid in the pressure-temperature phase diagram.

### EXAMPLE 2

In order to characterize the frozen films formed in Example 1, x-ray reflectivity (“XR”) was conducted at the X10B beamline of the National Synchrotron Light Source (NSLS), Brookhaven National Laboratory (BNL) using photon energy of 11 keV, i.e., x-ray wavelength (X) of 1.13A. X-ray reflectivity is sensitive to the vertical concentration profiles (i.e., thickness, density and roughness). A thin layer on a substrate will produce oscillations in the reflectivity related to the layer's thickness known as Kiessig fringes. The distance between adjacent fringes gives an indication of layer thickness.

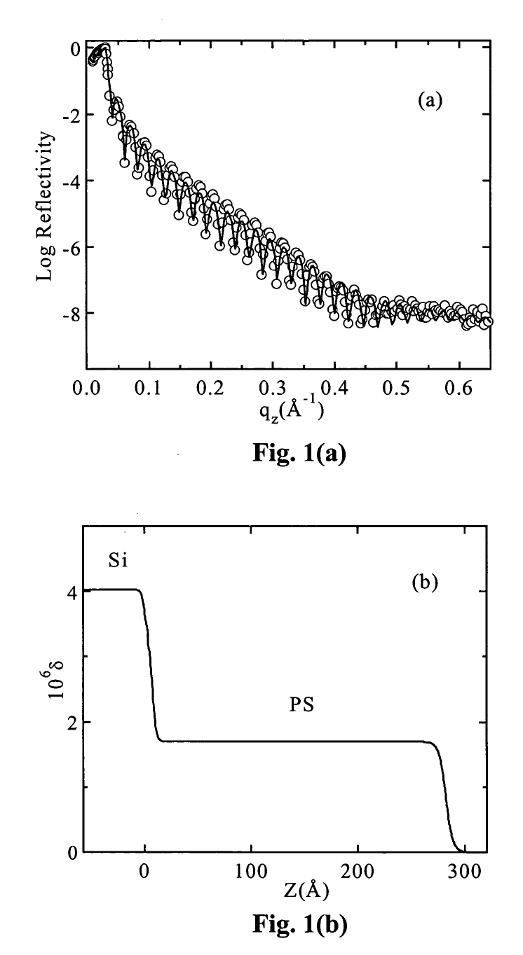

FIG. 1(a) shows the representative x-ray reflectivity profile for the frozen PS1 thin film, where the reflectivity is plotted as a function of the momentum transfer normal to the surface, q_{z}=4π sin θ/λ, where θ is the glancing angle of incidence. The unswollen film thickness (L₀) was estimated to be 223 Å, which is equivalent to 1.86 R_{g} (R_{g} is the radius of polymer gyration (=6.7 Å×(N/6)^{1/2}), where N is the polymerization index).

The reflectivity curve in FIG. 1(a) shows the persistence of the Kiessig fringes to the large q_{z} values. Based on the fitting analysis using the three-layers model, i.e., silicon substrate, native oxide and PS layer shown in FIG. 1(b), the root-mean-square (“rms”) roughness (“σ”) between the polymer and air layer was estimated to be 4.6±0.4 Å, which is approximately the same as the unswollen film. This shows that the density distribution of the frozen film is substantially as homogenous as that of the unswollen film. The SiO₂ layer of 8.5 Å thickness and the PS1 layer of 275 Å thickness with dispersion value of δ=1.70×10⁻⁶ in the x-ray refractive index were also obtained from the fitting. This dispersion value means that the density of the film is reduced by 12% (the bulk δ value is 1.90×10⁻⁶). The same model fitting for the x-ray reflectivity profiles showed that the homogenous low-density formation occurred in all of the films with thicknesses ranging from 100 to 400 Å.

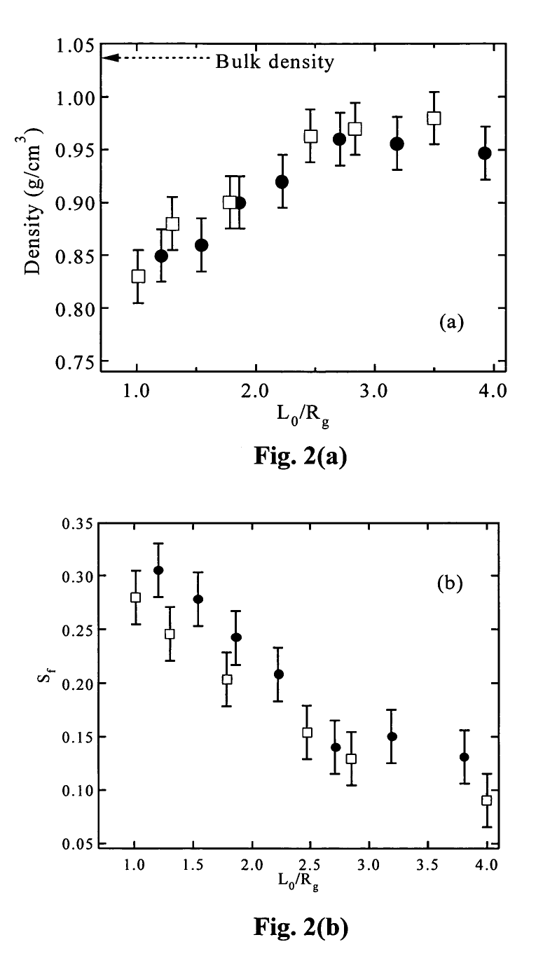

FIG. 2(a) is a graph which plots the density of the films versus the film thickness scaled by R_{g} (“L₀/R_{g}”) and shows that the density for both polymers (PS1 and PS2) decreased to 0.81±0.02 g/cm³ at L₀/R_{g}=1. FIG. 2(b) is a graph which plots the linear dilation (“S_{f}”) of both polymer films versus the scaled film thickness (“L₀/R_{g}”) and shows a decrease in linear dilation as the scaled film thickness increases. Hence, as the linear dilation increases, the density of the film decreases.

### EXAMPLE 3

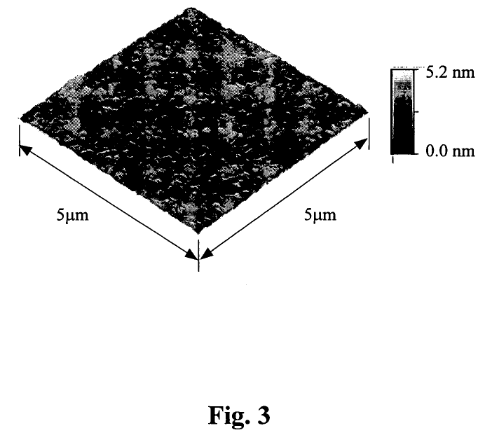

In this example, the films formed in Example 1 were tested using an atomic force microscopy (“AFM”) scan of the surface topography of the film. FIG. 3 shows an AFM scan of the surface topography for the frozen film PS1 (L₀=223 Å), where the surface appears flat with the roughness (σ) value of about 5 Å, which is consistent with the x-ray reflectivity results. Hence, the combination of the x-ray reflectivity and AFM results leads to an important conclusion that no additional large voids form via the vitrification process.

### EXAMPLE 4

In this example, the surface glass transition temperature (“T_{g}”) measurements for the CO₂-treated films formed in Example 1 were performed by AFM mode, shear modulation force microscopy (“SMFM”), which is sensitive to the large change in viscoelastic behavior at an air/polymer interface. In this method T_{g} is measured using a Digital Instruments Dimension 3000 coupled to an MMR Model R2700-2 sample heating/cooling stage with a temperature stability of 0.05° C. A small sinusoidal drive signal to the x-piezo was applied in a direction perpendicular to the fast scan direction inducing a small oscillatory motion of the cantilever tip parallel to the sample surface. At the same time, a normal force is applied to maintain tip contact with the sample. The lateral deflection amplitude of the tip, ΔX, which is proportional to the lateral force can be measured as a function of temperature using a lock-in amplifier, tuned to the drive frequency. The lateral force is directly proportional to the contact area which in turn scales with the elastic modulus. At T_{g} the elastic modulus decreases by three orders of magnitude which manifests itself as an abrupt increase in the deflection amplitude. Hence, by detecting the kink in the response of ΔX as a function of temperature, T_{g} can be determined.

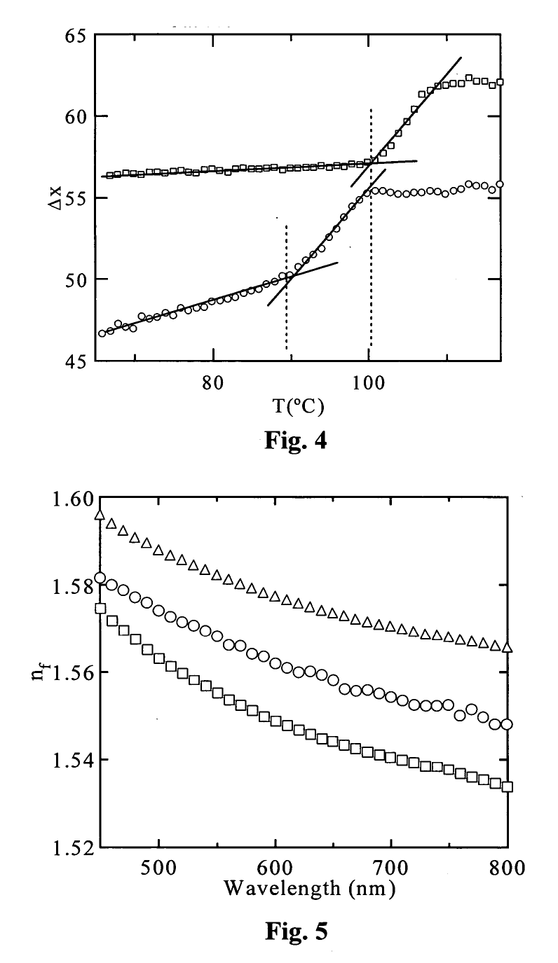

The polymer used was PS2 and the temperature was increased from room temperature up to 120° C. at a rate of 1.0° C. per minute. FIG. 4 shows the temperature dependence of the amplitude response of shear force (“Δx”) on a tip modulated parallel to the film surfaces with and without CO₂ treatment. The upper curve in FIG. 4 is for the unswollen film and the lower curve is for the frozen film, i.e., the film contacted with scCO₂. The intersection of the two straight lines fit to the data for each curve is identified as T_{g}. As can be seen in the figure, the T_{g} value for the PS2 frozen film (S_{f}=0.13, L₀=382 Å) decreases about 10° C. compared with that of the unswollen PS2 films (T_{g}=100° C.).

### EXAMPLE 5

In this example, the corresponding change of optical refractive indices for the frozen films formed in Example 1 was measured by using spectroscopic ellipsometry. An H-VASE spectroscopic ellipsometry (J.A. Woollam Co., Inc.) was used with a wide spectral range of 300-800 nm with 10 nm increments. The angle of incidence beam for all the measurements was varied from 60° to 75° with 5° increments from the vertical. In order to fit the spectroscopic data, the same three-layer model as the x-ray reflectivity analysis was used with the refractive indices obtained from published literature for the native oxide and silicon substrate. The film thickness was determined accurately by x-ray reflectivity so that the only parameter for the ellipsometry data fitting was the refractive index of the PS2 layer.

FIG. 5 shows the refractive indices (“n_{f}”) of the PS2 layers for the untreated and two frozen films with different S_{f} values. The figure shows that the refractive indices for the frozen CO₂ films decreased with increasing linear dilation (S_{f}) values over a wide wavelength range of 450-800 nm. The dielectric constant of materials is equal to the square of the refractive index. Using this relationship, the dielectric constants for the frozen and unfrozen films were calculated. The results showed that there was approximately a 4% decrease in the dielectric constant of the frozen film with S_{f}=0.21 compared to the unfrozen film.

### EXAMPLE 6

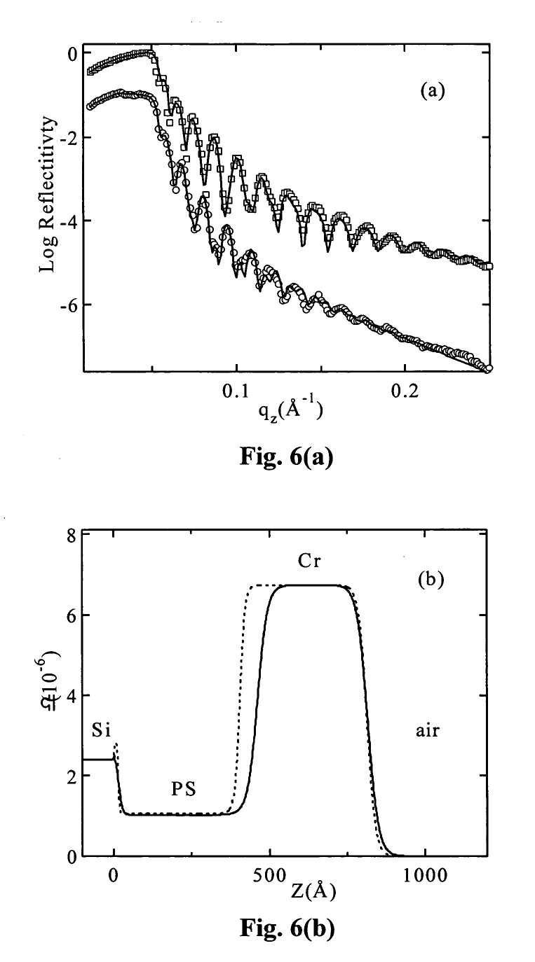

In this example, chromium (Cr) was deposited onto the films formed in Example 1 by using an E-beam Evaporator (Model 9320026, Varian Vacuum System). The thickness of the Cr layer was approximately 400 Å. An unswollen PS/Cr specimen was also prepared as a controlled specimen. It should be noted that the thickness of the Cr layer for each specimen was slightly different. FIG. 6(a) shows the x-ray reflectivity curves for PS1 films with CO₂ treatment with λ=0.87 Å(lower curve) and without CO₂ treatment (upper curve). The x-ray reflectivity data were fitted by using standard multilayers fitting routine for the dispersion value (δ) in the x-ray refractive index. A four layers model, i.e., Si substrate, the native oxide (SiO₂), PS1 layer and Cr layer was used to fit the data. The δ values of Si, SiO₂ and Cr layers were calculated to be 2.39×10⁻⁶, 2.54×10⁻⁶ and 6.7×10⁻⁶, respectively, and the only 6 value of the PS1 layer was determined from the fit. The roughness of each interface between the layers was assumed to be a given Gaussian smoothing function with standard deviation σ, and the dispersion profile across the interface between the layers was expressed as a convolution of a step function having the given film thickness and the Gaussian function.

The solid lines in FIG. 6(a) are best-fits to the data based on the corresponding dispersion profiles shown in FIG. 6(b). From the fitting result, the linear dilation (S_{f}) of the PS1 film was estimated to be 0.13 and the density of the layer, which is proportional to the 6 value, decreased by about 10%. It was also observed that the interfacial width (w), which is expressed as w=\sqrt{2π}σ, between the PS1 and Cr layer for the frozen film increased by a factor of 2 (w=58 Å) compared to that of the unswollen film (w=29 Å). It should be noted that σ value at the air/Cr interface for the frozen film was almost identical (21.5±0.7 Å) to that for the unswollen film (19.1±0.7 Å), indicating that dewetting caused by the CO₂ processing did not take place at the interface. Thus, it was determined that low-density surfaces produced in scCO₂ can also be used for enhanced adhesion of polymer/metal interface for vapor deposition. This could be very important for microelectronics devices since adhesion at the interface created is very important, especially because such interfaces must often survive accelerating testing involving thermal and humidity cycling to ensure their reliability.

### EXAMPLE 7

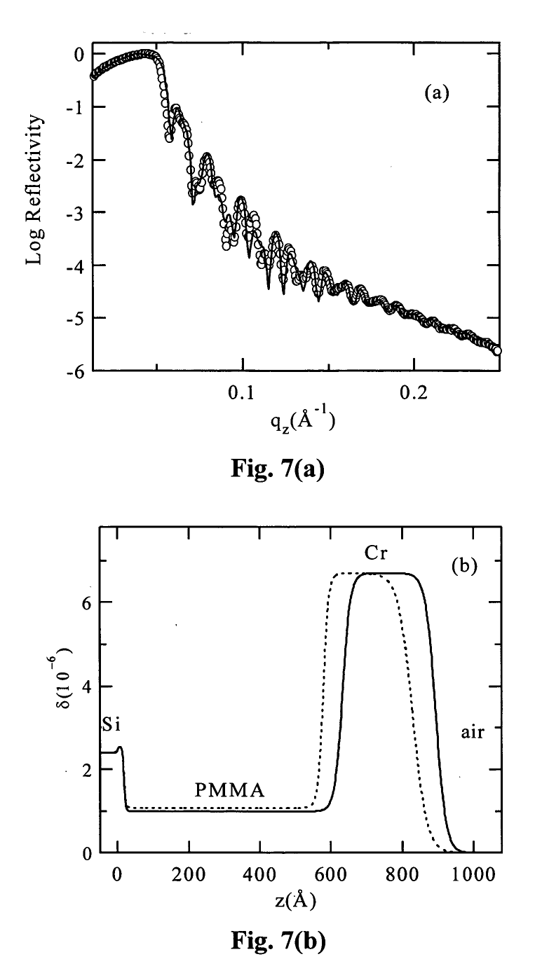

In this example, low density, metalizable, thin poly(methyl methacrylate) (“PMMA”) films were formed using the same method that was used in Example 1. PMMA is a high modulus, high gloss, glassy polymer which is naturally transparent and colorless and often used as a replacement for glass. The PMMA that was used had a molecular weight (M_{w}) of 1.2×10⁵ and a polydispersity index of 1.05. This PMMA polymer was obtained from Polymer Lab. FIG. 7(a) shows the x-ray reflectivity data for the PMMA/Cr (i.e., the thin PMMA films with the Cr metallization) with CO₂ treatment with λ=0.87 Å (lower curve) and without CO₂ treatment (upper curve). By using the same four layer model described in Example 6, it was found that the density of the PMMA film decreased 10% and the interfacial width at the PMMA/Cr interface for the exposed film increased (42 Å), compared to 28 Å for the unswollen PMMA film (FIG. 7(b)). This indicates that scCO₂ significantly enhances the adhesion of polymer/metal interfaces for vapor deposition.

### EXAMPLE 8

In this example, films were formed using the same method used in Example 1, except supercritical ethane (scC₂H₆, Tc=32.4° C. and Pc=4.9 MPa) was used in place of supercritical CO₂. In situ neutron reflectivity results showed anomalous swelling behavior at the density fluctuation ridge of supercritical ethane similar to the density fluctuation ridges for films immersed in scCO₂.

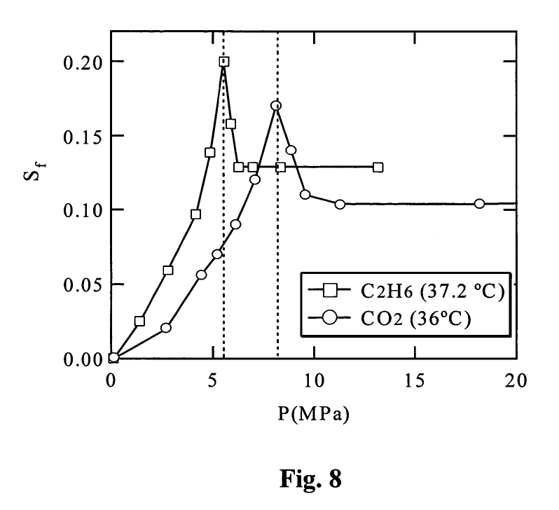

FIG. 8 shows the swelling behavior of the deuterated polystyrene (d-PS) thin film, where deuteration would provide neutron scattering contrast, in scCO₂ and scC₂H₆ by using in situ neutron reflectivity experiments. The d-PS that was used had a molecular weight (Mw) of 4.0×10⁵ and a polydispersity index of 1.05. The d-PS was obtained from Polymer Source. The figure shows that the anomalous swelling peak was also observed at the ridge for C₂H₆ (T_{c}=37.2° C., P_{c}=5.3 MPa). In addition, the maximum swelling of the d-PS thin film in scC₂H₆ was larger than that in scCO₂, indicating that the miscibility between C₂H₆ and the polymer is better. This indicates that even lower density (with lower-dielectric constant) films can be formed using scC₂H₆ as a replacement for scCO₂.

### EXAMPLE 9

In this example, hydrogenated polystyrene and gold nanoparticles were used. The hydrogenated polystyrene (“PS”) that was used had a molecular weight (M_{w}) of 2.9×10⁵ and had polydispersity index of 1.05. The PS3 polymer was obtained from Polymer Lab. Thiol-functionalized gold nanoparticles were prepared by using the one phase synthesis method developed by Ulman and co-workers. The average radius of the gold particles was estimated to be about 2 nm, based on the transmission electron microscopy measurements. A solution of PS3 was first prepared in toluene. The C₈ functionalized gold (weight percentage 4%) was then added to the PS3 solution and further sonicated for 1 hour. The solution appeared to be stable, indicating the particles were miscible with the polymer. Polymeric nanocomposite thin films were prepared by spin-casting onto HF-etched Si substrates and annealed for 5 hours in a vacuum of 10⁻³ Torr at T=150° C.>T_{g}, in order to remove residual solvents and spin-induced stress. The films were then formed using the same method that was used in Example 1.

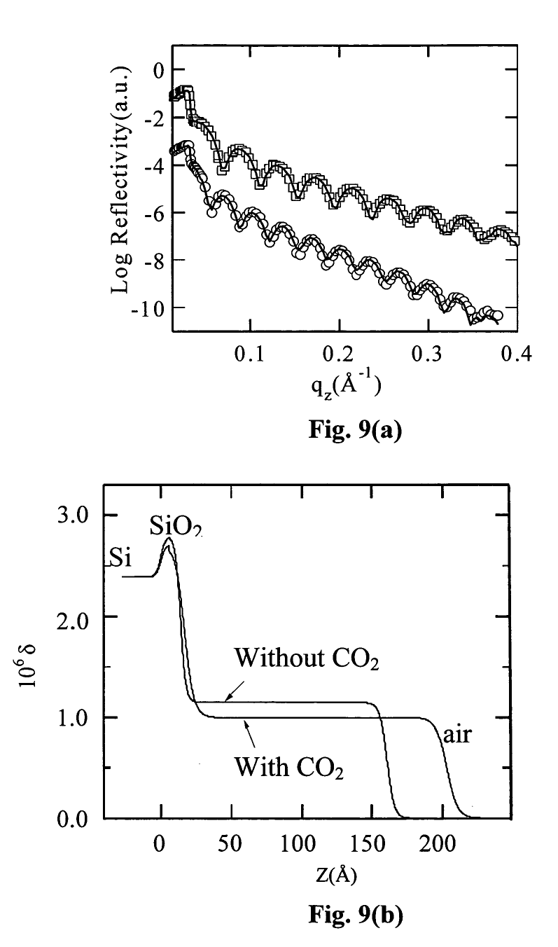

FIG. 9(a) shows x-ray reflectivity profiles for the PS3/gold, initially 1 R_{g} thick (144 Å), before and after exposure to scCO₂. The solid lines are best-fits to the data based on the three-layer model shown in FIG. 9(b), where the dispersion value in the x-ray refractive index δ corresponding to the silicon substrate, native oxide and PS3 layers is plotted. Good fits could be obtained with a uniform polymer concentration, i.e., no preferential adsorption of either the gold particles or polymer chains occurs at the air/polymer or polymer/Si interfaces before and after exposure to scCO₂. The linear dilation (S_{f}) of the PS3/gold film was estimated to be 0.27. This value is slightly smaller than S_{f}=0.35 for the pure PS3 thin film with the same initial thickness formed using the same method used in Example 1.

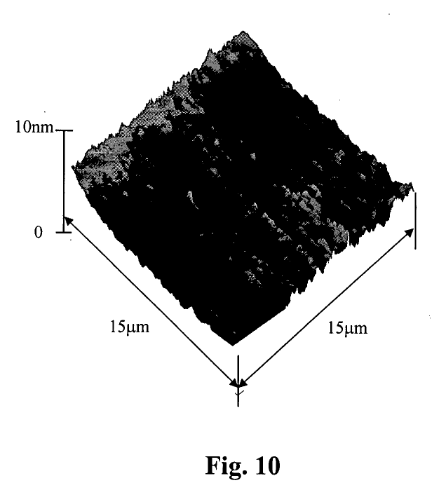

It is important to point out that the homogenous dispersion 6 value of the exposed PS3/gold film (δ=1.0×10⁻⁶) has decreased by 14% relative to that of the unexposed PS3/gold film (δ=1.15×10⁻⁶). Hence, it is reasonable to say that a uniform low-density layer with the density reduction of 14% is formed through the frozen film. Examination of the data also showed that exposure to scCO₂ caused an increase from 4.5±0.5 Å to 6.8±0.5 Å in root-mean-square (rms) roughness between the polymer and air layers. In order to see whether this increase is related to segregation of the gold particles, the surface morphology of the exposed film was scanned with AFM in series of 100 μm×100 μm scans across the entire sample surface. As shown in FIG. 10, no gold aggregations were observed and the surface remained flat and featureless. Therefore, it can be concluded that exposure to scCO₂ in the density fluctuating regime can be used to produce a uniform low-density polymer-gold nanocomposite thin film.

### EXAMPLE 10

In this example, PS3 and organoclay were used in order to determine whether the low-density nanocomposite film can be created regardless of a choice of nanoparticles. Commercially available organoclay (Bentone-34), consisting of SiO₂ (˜50%) and various oxides (Al₂O₃, MgO, CaO, Na₂O, K₂O and Fe₂O₃), was used. The intercalation organic molecules were dimethyl, dehydrogenatedtallow ammonium (2M2HT). The solution of PS3 was first prepared in toluene. The organoclay (weight percentage 0.2%) was then added to the PS3 solution and further sonicated for 1 hour. The films were formed by using the same method that was used in Example 9.

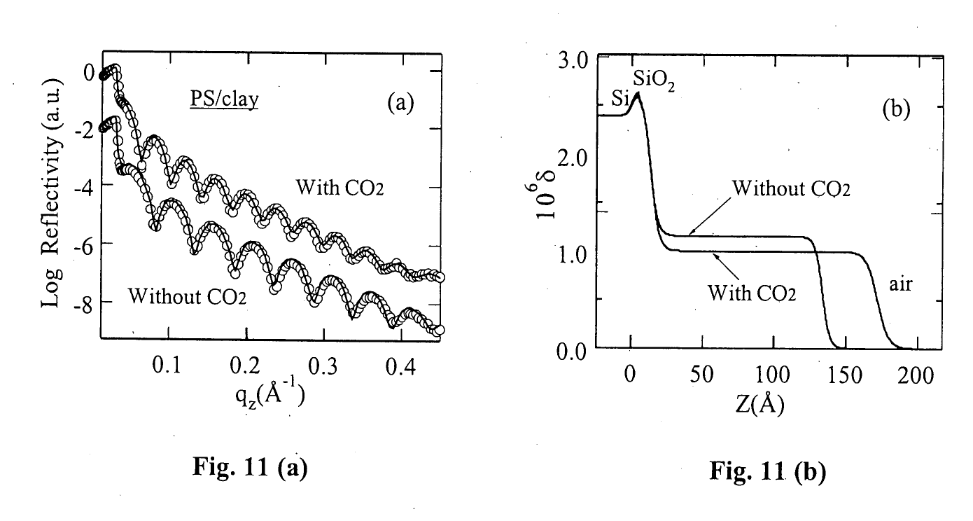

FIG. 11(a) shows x-ray reflectivity profiles for the PS3/clay thin film (L₀=120 Å) before and after exposure to scCO₂. The best-fits to the data based on the dispersion model shown in FIG. 11(b) indicates that the layer of the exposed PS3/clay film has thickened (L=151 Å) with the reduced dispersion value of 8=1.0×10⁻⁶, which is identical to that of the exposed PS3/gold film. Hence, it is obvious that the formation of uniform low-density polymer layers with nanoparticles is independent of the nature of the particles.

### EXAMPLE 11

In this example, the surface glass transition temperature (“T_{g}”) measurements for the CO₂-treated nanocomposite films formed in Example 10 were performed by AFM mode, shear modulation force microscopy (“SMFM”) that was used in Example 4. The film formed in Example 10 was used and the temperature was increased from room temperature up to 120° C. at a rate of 1.0° C. per minute.

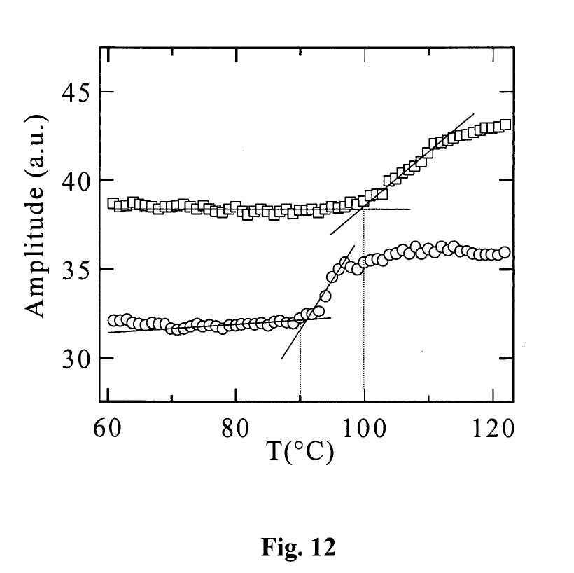

FIG. 12 plots the modulation amplitude, ΔX vs. T for the unexposed PS3/gold film (shown as “□”) and the film exposed to scCO₂ (shown as “∘”), for films 2 R_{g} thick (290 Å). The figure shows that the discontinuity of slope in the plot occurs at T=100° C. for the unexposed PS3/gold film. The T_{g} value for the exposed film is seen to decrease by 10° C. compared to that of the unexposed PS3/gold film. Interestingly, the degree of the T_{g} reduction in the exposed PS3/gold thin film was equivalent to that of the exposed polystyrene film formed in Example 1. Furthermore, it was found that the T_{g} values for the exposed PS3/gold films were constant (T_{g}=90° C.), irrespective of the film thickness. It should be added that the similar reduction in T_{g} was observed in the exposed PS3/organoclay thin films.

Thus, while there have been described the preferred embodiments of the present invention, those skilled in the art will realize that other embodiments can be made without departing from the spirit of the invention, and it is intended to include all such further modifications and changes as come within the true scope of the claims set forth herein.

1. A method for improving the physical properties of a polymer film comprising contacting a polymer film with a supercritical fluid (“SCF”).

2. The method for improving the physical properties of a polymer film according to claim 1, wherein the SCF is supercritical carbon dioxide (“scCO₂”) or supercritical ethane (“scC₂H₆”).

3. The method for improving the physical properties of a polymer film according to claim 1, wherein the density is decreased by at least 20%.

4. The method for improving the physical properties of a polymer film according to claim 1, wherein the glass transition temperature is reduced.

5. The method for improving the physical properties of a polymer film according to claim 1, wherein the nanoscale-porosity is increased.

6. The method for improving the physical properties of a polymer film according to claim 1, wherein the index of refraction of the polymer film is changed.

7. The method for improving the physical properties of a polymer film according to claim 1, wherein the dielectric constant of the film is decreased.

8. The method for improving the physical properties of a polymer film according to claim 1, wherein the polymer film comprises a polystyrene or a poly(methyl methacrylate).

9. The method for improving the physical properties of a polymer film according to claim 1, wherein the polymer film comprises nanoscale inorganic particles with a diameter of from about 1 nm to about 100 nm.

10. The method for improving the physical properties of a polymer film according to claim 1, wherein the nanoscale inorganic particles comprise noble metals.

11. The method for improving the physical properties of a polymer film according to claim 1, wherein the SCF contacts the polymer film at high pressure and high temperature conditions.

12. The method for improving the physical properties of a polymer film according to claim 1, wherein the high temperature and the high pressure conditions correspond to the SCF's density fluctuation ridge conditions.

13. A method for improving the physical properties of a polymer film comprising contacting a polymer film comprising a polystyrene or a poly(methyl methacrylate) with a supercritical fluid (“SCF”), wherein the SCF is supercritical carbon dioxide (“scCO₂”) or supercritical ethane (“scC₂H₆”).

14. The method for improving the physical properties of a polymer film according to claim 13, wherein the SCF contacts the polymer film at high pressure and high temperature conditions which correspond to the SCF's density fluctuation ridge conditions.

15. A method for reducing the density of a polymer film comprising contacting a polymer film with a supercritical fluid (“SCF”).

16. The method for reducing the density of a polymer film according to claim 15, wherein the SCF is supercritical carbon dioxide (“scCO₂”) or supercritical ethane (“scC₂H₆”).

17. The method for reducing the density of a polymer film according to claim 16, wherein the density is decreased by at least 20%.

18. A polymer film with improved physical properties comprising a polymer layer treated with a supercritical fluid (“SCF”).

19. The polymer film in accordance with claim 18, wherein the polymer layer comprises a polystyrene or a poly(methyl methacrylate).

20. The polymer film in accordance with claim 18, wherein the SCF is supercritical carbon dioxide (“scCO₂”) or supercritical ethane (“scC₂H₆”).

21. The polymer film in accordance with claim 18, wherein the SCF contacts the polymer film at high pressure and high temperature conditions.

22. The polymer film in accordance with claim 18, wherein the high temperature and the high pressure conditions correspond to the SCF's density fluctuation ridge conditions.

23. The polymer film in accordance with claim 18, wherein the polymer film comprises nanoscale inorganic particles with a diameter of from about 1 nm to about 100 nm.

24. The polymer film in accordance with claim 18, wherein the nanoscale inorganic particles comprise noble metals.

25. A polymer film with improved physical properties comprising a polymer layer comprising a polystyrene or a poly(methyl methacrylate), wherein said polymer layer is treated with supercritical carbon dioxide (“scCO₂”) or supercritical ethane (“scC₂H₆”) at high pressure and high temperature conditions which correspond to the density fluctuation ridge conditions of the scCO₂ or the scC₂H₆.

26. The polymer film in accordance with claim 25, wherein the polymer film further comprises nanoscale inorganic particles with a diameter of from about 1 nm to about 100 nm.

27. A method for coating a polymer film comprising:
contacting a polymer film with a supercritical fluid (“SCF”);
flash evaporating the SCF; and
contacting the polymer film with a metallic vapor.

28. The method of coating a polymer film according to claim 27, wherein the polymer film comprises a polystyrene or a poly(methyl methacrylate).

29. The method of coating a polymer film according to claim 27, wherein the SCF is supercritical carbon dioxide (“scCO₂”) or supercritical ethane (“scC₂H₆”).

30. The method of coating a polymer film according to claim 27, wherein the SCF contacts the polymer film at high pressure and high temperature conditions which correspond to the SCF's density fluctuation ridge conditions.

31. The method of coating a polymer film according to claim 27, wherein the SCF contacts the polymer film for at least 30 minutes.

32. The method of coating a polymer film according to claim 27, wherein the polymer film comprises nanoscale inorganic particles with a diameter of from about 1 nm to about 100 nm.

33. The method of coating a polymer film according to claim 27, wherein the nanoscale inorganic particles comprise noble metals.

34. A method for coating a polymer film comprising:
contacting a polymer film comprising a polystyrene or a poly(methyl methacrylate) with a supercritical fluid (“SCF”), wherein the SCF is supercritical carbon dioxide (“scCO₂”) or supercritical ethane (“scC₂H₆”) and wherein the SCF contacts the polymer film at high pressure and high temperature conditions which correspond to the SCF's density fluctuation ridge conditions;
flash evaporating the SCF; and
contacting the polymer film with a metallic vapor.

35. The method of coating a polymer film according to claim 34, wherein the polymer film comprises nanoscale inorganic particles with a diameter of from about 1 nm to about 100 nm.

36. The method of coating a polymer film according to claim 34, wherein the metallic vapor comprises aluminum, tin, silver, chromium or gold.
